(19) United States
(12) Patent Application Publication
(10) Pub. No.: US 2006/0024901 A1
(43) Pub. Date: Feb. 2, 2006

(54) Method for fabricating a high-frequency and high-power semiconductor module

(75) Inventor: Shao-Pin Ru, Taipei (TW)

Correspondence Address: NIKOLAI & MERSEREAU, P.A., 900 SECOND AVENUE SOUTH, SUITE 820, MINNEAPOLIS, MN, 55402, US

(73) Assignee: Tong Hsing Electric Industries Ltd., Taipei (TW)

(21) Appl. No.: 10/909,877

(22) Filed: Aug. 2, 2004

(51) Int. Cl. H01L 21/20; H01L 21/44

(52) U.S. Cl. 438/382; 438/614; 438/381; 438/384; 438/613; 438/687

(57) ABSTRACT

A method for fabricating a high-frequency and high-power semiconductor module uses two stages respectively adopting a thick-film process to form resistors or elements of high impedance, and a thin film process to form precise circuit wires or elements.

### BACKGROUND OF THE INVENTION

1. Field of the Invention

The present invention relates to a method for fabricating a high-frequency and high-power semiconductor module, more particularly, the method performs a first stage using thick-film processes employed to produce high impedance resistors and a second stage using thin-film processes to fabricate other precise elements.

2. Description of Related Art

The so-called thick-film process utilized in semiconductor fabricating technology is to produce a film with a thickness from a few micrometers (μ) to 20 micrometers μ. When forming the thick film, a colloid compound of metal powder, metallic oxide powder, glass powder, and organic colloid solvent are firstly prepared. The colloid compound then is printed to form desired grill patterns and further sintered at high temperature, i.e. approximately 500-1000 degrees Centigrade thereby forming a thick film. Such a thick film is usually applied in the manufacturing of resistors, conductors, capacitors, multi-layer wires or protective glass film.

Differing from the thick-film process, the thin-film process uses the compound of the metal, alloy, insulation material and other chemical compositions as the raw material and forms thin films with the thickness from a few angstroms (Å) to a few micrometers (μ) through sputtering, vapor deposition etc. The thin film is also widely used to produce resistors, conductors, capacitors, multi-layer wires and protective glass films. In comparison to the thick-film process, elements manufactured with the thin-film process possess superior precision but involve higher cost.

The characteristic of low impedance and power of resistors manufactured through the thin film process are unsuitable for high frequency modules that require higher power. Although the thick-film process can fit such power requirements, it is unable to form precision circuit patterns.

Therefore, the invention provides a method for fabricating a high-frequency and high-power semiconductor module to mitigate or obviate the aforementioned problem.

### SUMMARY OF THE INVENTION

The main objective of the present invention is to provide a method for fabricating a high-frequency and high-power semiconductor module in which resistors of high impedance and passive elements as well as precise circuits are all integrated therein.

To accomplish the objective, the method comprises two stages, wherein a first stage uses a thick-film process to form resistors and circuits requiring high impedance; and a second stage uses a thin-film process to form electrical components and circuits requiring high precision.

Other objectives, advantages and novel features of the invention will become more apparent from the following detailed description when taken in conjunction with the accompanying drawings.

### BRIEF DESCRIPTION OF THE DRAWINGS

FIG. 1 is a flowchart of a first stage of the method in accordance with the present invention; and

FIG. 2 is a flowchart of a second stage of the method in accordance with the present invention.

### DETAILED DESCRIPTION OF THE PREFERRED EMBODIMENT

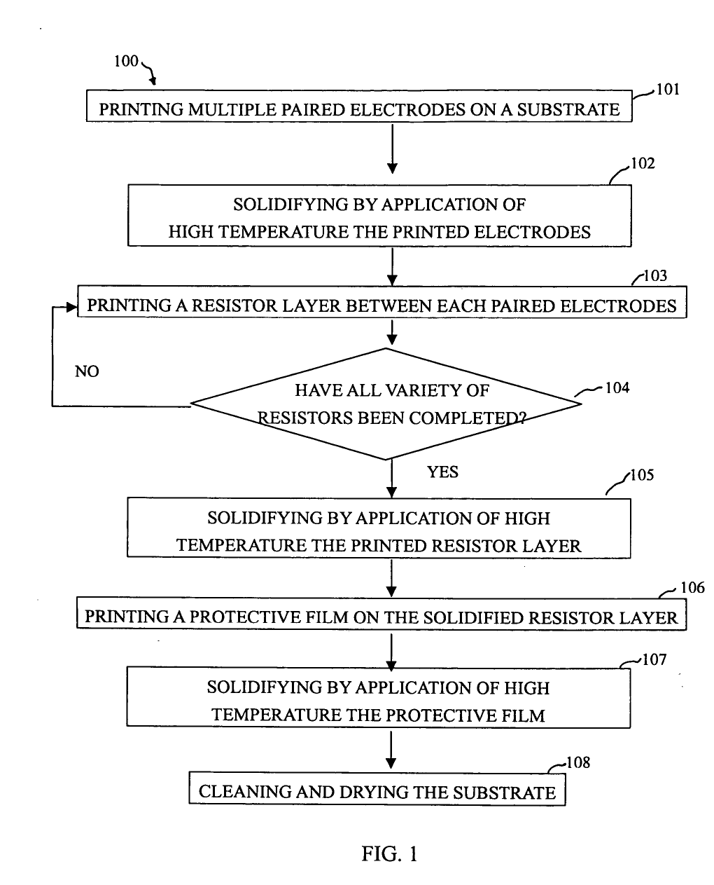

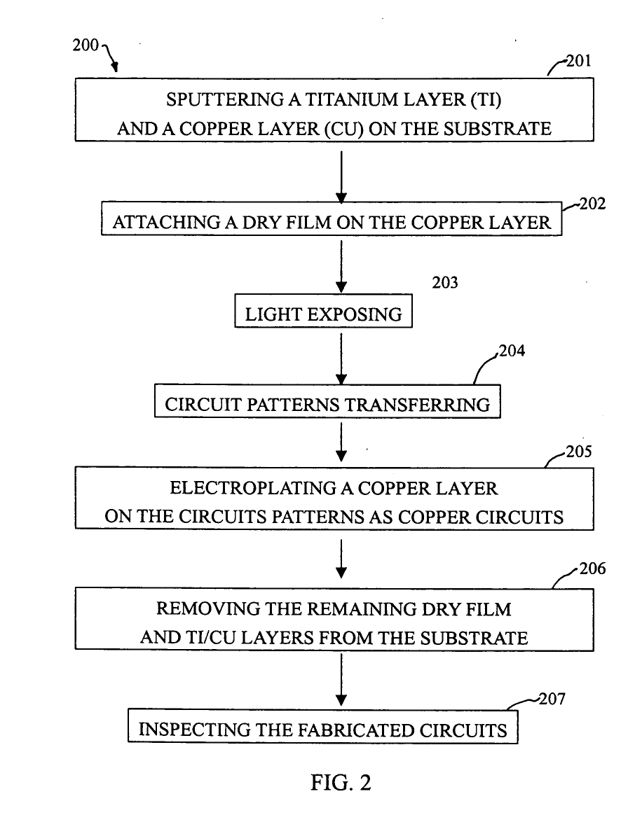

With reference to FIGS. 1-2, a method of the invention mainly comprises a first stage (100) and a second stage (200). The first stage (100) employs the thick-film process to form electrical elements of high impedance. The second stage (200) uses the thin-film process to form electrical elements of high precision.

The first stage (100) involves the acts as follows:
printing multiple paired electrodes on a substrate as paired terminals of resistors (step 101);
solidifying by application of high temperature the printed electrodes (step 102);
printing a resistor layer between each paired electrodes until one or a variety of resistors have been completed (steps 103 and 104), wherein the repetition of resistor layer printing depends on the kinds of the resistors to be printed;
solidifying by application of high temperature the printed resistor layer (step 105);
printing a protective film on the solidified resistor layer (step 106);
solidifying by application of high temperature the protective film (step 107); and
cleaning and drying the substrate (step 108).

Besides the forming of the resistors, the foregoing first stage (100) can be applied to form circuits of high impedance. Subsequent to the first stage of forming the resistors, the second stage (200) using thin-film process is introduced to produce other precise elements and circuits, which comprises the acts of:
sequentially sputtering a titanium layer (Ti) and a copper layer (Cu) on the substrate (step 201);
attaching a dry film on the copper layer (step 202);
transferring circuit patterns over the dry film from a photo-mask through photolithography (steps 203 and 204);
electroplating a copper layer on the circuits patterns as copper circuits (step 205);
removing the remaining dry film and Ti/Cu layers from the substrate to complete forming of the thin-film circuits.

In conclusion, the method for forming a high frequency, high power semiconductor module in accordance with the present invention integrates the advantages of the respective thin-film and thick-film processes through two stages, whereby the semiconductor module can simultaneously possess resistors with high impedance and precise circuits.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method for fabricating a high-frequency and high-power semiconductor module, the method comprising the acts of:
a first stage using a thick-film process to form resistors and circuits requiring high impedance; and
a second stage using a thin-film process to form electrical components and circuits requiring high precision.

2. The method as claimed in claim 1, wherein the first stage comprises the acts of:
printing multiple pairs of electrodes on a substrate as terminals of the resistors;
solidifying by application of high temperature the printed electrodes;
printing a resistor layer between each pair of electrodes as a resistor until all resistors have been completed;
solidifying by application of high temperature the printed resistor layer;
printing a protective film on the solidified resistor layer;
solidifying by application of high temperature the protective film; and
cleaning and drying the substrate.

3. The method as claimed in claim 1, wherein the second stage comprises the acts of:
sequentially sputtering a titanium layer (Ti) and a copper layer (Cu) on the substrate;
attaching a dry film on the copper layer;
transferring circuit patterns over the dry film from a photo-mask through a photolithography process;
electroplating a copper layer on the circuits patterns as copper circuits; and
removing remaining dry film and Ti/Cu layers from the substrate.

4. The method as claimed in claim 2, wherein the second stage comprises the acts of:
sequentially sputtering a titanium layer (Ti) and a copper layer (Cu) on the substrate;
attaching a dry film on the copper layer;
transferring circuit patterns over the dry film from a photo-mask through a photolithography process;
electroplating a copper layer on the circuits patterns as copper circuits; and
removing remaining dry film and Ti/Cu layers from the substrate.
